(19) United States
(12) Patent Application Publication
(10) Pub. No.: US 2024/0124966 A1
(43) Pub. Date: Apr. 18, 2024

(54) MASK AND METHOD FOR MANUFACTURING THE SAME, AND MASK ASSEMBLY AND METHOD FOR MANUFACTURING THE SAME

(71) Applicant: KunShan Go-Visionox Opto-Electronics Co., Ltd, Kunshan (CN)

(72) Inventors: Weili LI, Kunshan (CN); Wenxing LI, Kunshan (CN); Gongzheng ZANG, Kunshan (CN); Bing HAN, Kunshan (CN); Jishuai ZHANG, Kunshan (CN); Mudan CHEN, Kunshan (CN)

(73) Assignee: KunShan Go-Visionox Opto-Electronics Co., Ltd, Kunshan (CN)

(21) Appl. No.: 18/539,805

(22) Filed: Dec. 14, 2023

Related U.S. Application Data
(63) Continuation of application No. PCT/CN2022/109401, filed on Aug. 1, 2022.

(30) Foreign Application Priority Data
May 23, 2022 (CN) 202210565405.4

(51) Int. Cl. C23C 14/04; H10K 71/16

(52) U.S. Cl. CPC C23C 14/042; H10K 71/166

(57) ABSTRACT

A mask, including a first clamping region and a second clamping region opposite to each other in a first direction, and at least one mask opening region disposed between the first clamping region and the second clamping region. The mask opening region is in a first initial shape before being tensioned. The mask opening region is in a first target shape during an evaporation deposition process. The first initial shape is different from the first target shape. The first initial shape includes a compensation pattern with respect to the first target shape. The compensation pattern includes a tensile deformation pattern and a thermal deformation pattern.

### CROSS-REFERENCE TO RELATED APPLICATION

This application is a continuation of international patent application No. PCT/CN2022/109401, filed on Aug. 1, 2022, which claims priority to Chinese Patent Application No. 202210565405.4, entitled “MASK AND METHOD FOR MANUFACTURING THE SAME, AND MASK ASSEMBLY, AND METHOD FOR MANUFACTURING DISPLAY SUBSTRATE” filed on May 23, 2022. The contents of the above identified applications are hereby incorporated herein in their entireties by reference.

### TECHNICAL FIELD

The present disclosure relates to the field of display technology, and in particular to a mask and a method for manufacturing the same, a mask assembly, and a method for manufacturing a display substrate.

### BACKGROUND

Organic light-emitting diode (OLED) display technology has the advantages of self-illumination, high contrast, high resolution, wide viewing angle, low power consumption, fast response, and low manufacturing cost, and is regarded as the most promising new flat panel display technology for the next generation. Functional layers such as an organic light-emitting layer of the OLED display panel are usually prepared through an evaporation deposition method by using a fine metal mask (FMM). Therefore, the precision of the FMM determines the manufacturing precision of the functional layers such as the organic light-emitting layer.

### SUMMARY

In view of this, there is a need to provide a mask that can ensure precision of the evaporation deposition, effectively ameliorate the color mixing defect, and increase the product yield.

According to an aspect of the present disclosure, a mask is provided, including:
a first clamping region and a second clamping region opposite to each other in a first direction; and
at least one mask opening region disposed between the first clamping region and the second clamping region;
wherein the mask opening region is in a first initial shape before being tensioned, the mask opening region is in a first target shape during an evaporation deposition process, and the first initial shape is different from the first target shape; and
the first initial shape includes a compensation pattern with respect to the first target shape, and the compensation pattern includes a tensile deformation pattern and a thermal deformation pattern.

In this way, pre-compensation is applied for thermal and force collaboratively induced uneven deformation of the mask during mask tensioning in various directions and evaporation deposition process. This can reduce the deviation between the positions of a mask opening in the mask and a corresponding pixel opening in a display substrate, and diminish the difference between actual and designed boundaries of the evaporation-deposited layer. As such, the precision of the evaporation deposition can be ensured, the color mixing defect can be ameliorated, and the product yield can be increased.

According to another aspect of the present disclosure, a mask assembly is provided, including a mask frame and the mask according to any of the above embodiments, wherein the mask is disposed on the mask frame.

According to an aspect of the present disclosure, a method for manufacturing a mask is provided. The method includes:
providing a test mask, the test mask including at least one mask opening region, and the mask opening region being in a first target shape before being tensioned;
obtaining deformation state information of the mask opening region of the test mask during mask tensioning and evaporation deposition process of the test mask, the deformation state information including a tensile deformation trend, a tensile position deviation amount, an evaporation deposition thermal deformation trend, and an evaporation deposition thermal deformation amount of multiple position points within the mask opening region in a first direction and a second direction, wherein the first direction is parallel to a tensioning direction of the mask, and the second direction is perpendicular to the first direction;
obtaining reverse compensation information of the mask opening region according to the deformation state information, and obtaining target initial state information of the mask opening region according to the reverse compensation information; and
forming the mask according to the target initial state information, the formed mask including the mask opening region in a first initial shape, wherein the first initial shape includes a compensation pattern with respect to the first target shape, and the compensation pattern includes a tensile deformation pattern and a thermal deformation pattern.

According to another aspect of the present disclosure, a method for manufacturing a mask assembly is provided. The method includes adopting the mask according to any of the above embodiments to manufacture the mask assembly.

### BRIEF DESCRIPTION OF THE DRAWINGS

FIG. 1 is a deformation trend schematic view of a mask before and after an evaporation deposition process.

FIG. 2 is a schematic structural view of a mask frame.

FIG. 3 is a deformation trend schematic view of the mask shown in FIG. 1 before and after being subjected to a force.

FIG. 4 is a schematic view of a layout of mask opening regions of a test mask before being tensioned.

FIG. 5 is a schematic view of a layout of compensated mask opening regions of a mask after being compensated along a first direction in an embodiment of the present disclosure.

FIG. 6 is a schematic view of a layout of compensated mask opening regions of a mask after being compensated along a second direction in an embodiment of the present disclosure.

FIG. 7 is a schematic view of a layout of compensated mask opening regions of a mask after being compensated along a first direction and a second direction in an embodiment of the present disclosure.

FIG. 8 is a schematic structural view of a mask opening region of the mask shown in FIG. 7.

FIG. 9 is a schematic view of a layout of mask openings in a mask opening region in an embodiment of the present disclosure.

FIG. 10 is a schematic view of a layout of mask openings in a mask opening region in another embodiment of the present disclosure.

FIG. 11 is a schematic view of a layout of mask opening regions of a mask in an embodiment of the present disclosure.

FIG. 12 is a schematic view of a layout of mask opening regions of a mask in another embodiment of the present disclosure.

FIG. 13 is a flow chart of a method for manufacturing a mask in an embodiment of the present disclosure.

FIG. 14 is a simulation test graph showing deformation in a first direction of a mask opening region of a mask at a side away from the center of the mask in an embodiment of the present disclosure.

FIG. 15 is a simulation test graph showing deformation in a first direction of a mask opening region of a mask at a side adjacent to the center of the mask in an embodiment of the present disclosure.

FIG. 16 is a simulation test graph showing deformation in a second direction of a mask opening region of a mask in an embodiment of the present disclosure.

FIG. 17 is a schematic view of a mask assembly, showing positional relationships between a mask in different state before and after being compensated and a display substrate in an embodiment of the present disclosure.

FIG. 18 is a schematic view of the mask assembly shown in FIG. 17, showing the positional relationship between the compensated mask and the display substrate during an evaporation deposition process.

FIG. 19 is a flowchart of a method for manufacturing a mask assembly in an embodiment of the present disclosure.

### DETAILED DESCRIPTION

In order to facilitate understanding of the present disclosure, the present disclosure will be described more thoroughly hereinafter with reference to the accompanying drawings. Embodiments of the present disclosure are given in the accompanying drawings. However, the present disclosure may be implemented in various different forms and is not limited to the embodiments described herein. The purpose of providing these embodiments is to provide a more thorough and complete understanding of the present disclosure.

In organic light-emitting diode (OLED) display technology, the OLED display panel is current-driven and requires pixel driving circuits to connect the OLED devices of sub-pixels, providing driving current to the OLED devices for illumination. Each OLED device at least includes an anode, a cathode, and an organic light-emitting material located between the anode and the cathode. Taking a top-emitting OLED display panel as an example, the organic light-emitting material as the evaporation deposition material cannot be patterned using a conventional etching process due to its poor stability. Instead, an evaporation deposition process adopting a mask is used.

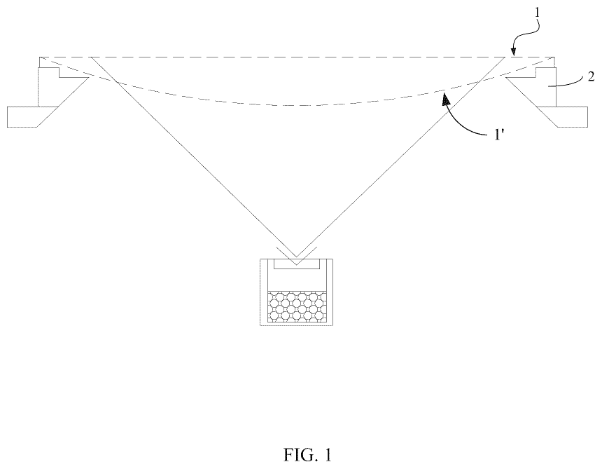

Referring to FIG. 1, the evaporation deposition process involves placing the evaporation deposition material in a vacuum environment, and heating to evaporate or sublimate the material. A mask assembly is disposed between the cavity for evaporating the material and the display substrate to be deposited with. A mask 1 of a mask assembly includes mask openings corresponding to the areas for deposition, but the areas where deposition is not required do not have any mask opening. The molecules of the evaporated or sublimated material travel through the mask openings and adhere to the display substrate to be deposited with, thereby directly forming a patterned layer on the display substrate. Taking an OLED light-emitting unit as an example, the unit can specifically include an electron injection layer, an electron transport layer, an organic light-emitting layer, a hole transport layer, a hole injection layer, etc. stacked with each other, wherein the electron injection layer, the electron transport layer, the hole transport layer, and the hole injection layer can be continuous layer structures formed through open masks. Taking the electron injection layer as an example, the electron injection layers of multiple sub-pixels are connected to each other and together form a continuous layer structure. In contrast, the organic light-emitting layer is a patterned layer structure corresponding to each sub-pixel, which is a layer formed by evaporation deposition using a fine metal mask (FMM).

Further, the OLED display panel also includes a pixel definition layer which defines multiple pixel openings, and the organic light-emitting layers of the sub-pixels are disposed in the pixel openings to avoid color mixing or interference between adjacent sub-pixels. Ideally, the position of the mask openings of the mask assembly is in correspondence with the position of the pixel openings, so that the evaporation deposition material can be accurately deposited on the corresponding positions of the display substrate. However, the precision of the fine metal mask is on the order of microns and thus requires high alignment accuracy with the display substrate. Typically, when the deviation between the position of the mask openings of the fine metal mask and the position of the pixel openings exceeds 5 microns, the deposited organic light-emitting materials are likely to have color mixing defects during display. The more fine metal masks are used, the more likelihood of the product defects, thus reducing the product yield.

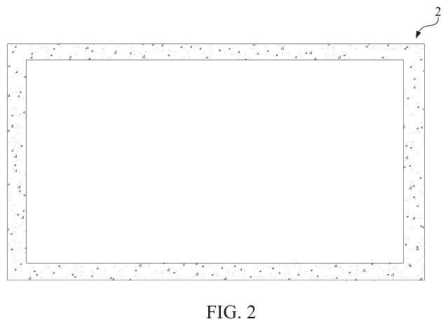

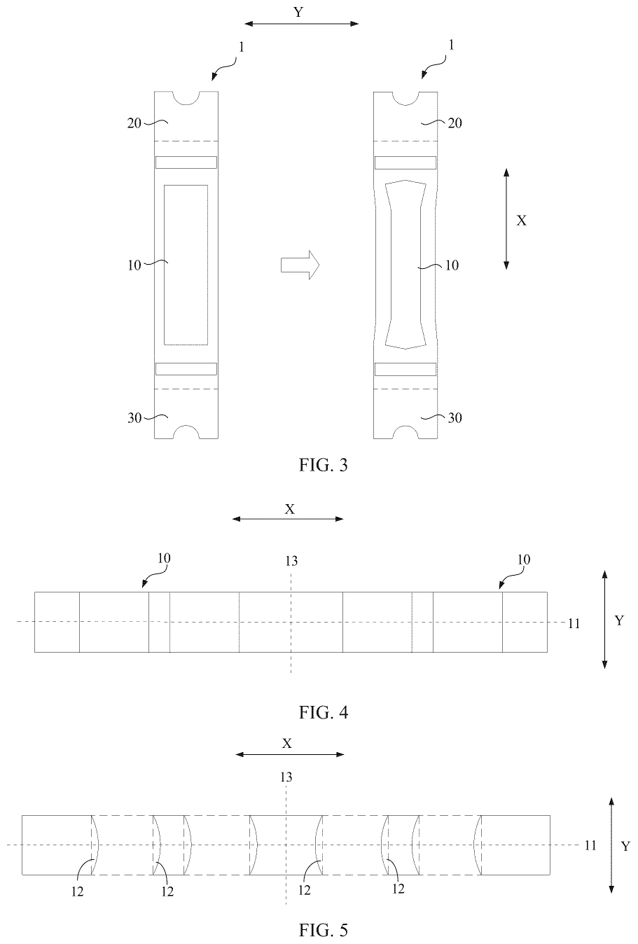

Currently, the fine metal mask used for evaporation deposition is relatively large in size and cannot be processed as one piece, but typically pieced by strip-shaped masks (also known as FMM sheets or strips). Each mask includes a mask opening region, and the mask opening region includes mask openings for evaporation deposition. Referring to FIG. 2, the mask frame is generally rectangular in shape. During the preparation of the mask assembly, the mask can be clamped and tensioned along the longitudinal direction of the mask by, for example, mechanical arms. By adjusting the tension, the mask openings of the mask opening region can be located at the target position. At this time, the two ends of the mask 1 are welded to a mask frame 2 through, for example, laser welding, thereby fixing the mask 1 onto the mask frame 2. However, the folds generated during the tensioning, the welding, etc. make it difficult for the mask 1 to maintain its pre-tensioned shape and size when being disposed on the mask frame 2. Referring to FIG. 3, the left part shows the schematic structural view of the mask 1 before being tensioned, and the right part shows the schematic structural view of the mask 1 that is tensioned. It can be seen that the shape and size of the mask opening region 10 of the tensioned mask 1 has changed correspondingly, resulting in misalignment between the mask openings and the pixel openings of the display substrate or an increase in shadows. This cannot be corrected through mask tensioning and subsequent processes, directly affecting the positional accuracy of the deposited sub-pixels, and thus resulting in display defects such as color spots and color shifts.

In order to make the shape and size of the mask openings of the mask opening region 10 reach a target state, the size of the mask 1 is compensated before being tensioned. For example, in an embodiment, the length of the mask 1 along the tensioning direction is shortened and the width of the mask 1 is widened, so that the sizes of the plurality of mask openings in the mask opening region can be adjusted accordingly. However, the inventors of the present application has found that since the mask includes various regions, such as the mask opening region 10, clamping regions 20, 30, welding regions, etc., these regions have different structures and different physical properties (such as Young's modulus, shear modulus, and Poisson's ratio). When a tensioning force is applied to the mask 1 through the clamping regions 20, 30 of the mask, the tensioning force is transferred to the mask opening region 10 through different regions. As a result, the mask opening region 10 receives different stresses at different positions, leading to different deformations in the mask opening area 10 at different positions. Correspondingly, the mask openings at different positions in the mask opening region 10 also can undergo different degrees of offset, and the offset amounts of the mask openings at different positions are not the same. As such, merely overall dimension compensation on the mask 1 cannot meet the precision requirements for manufacturing the mask 1.

The inventors of the present application further found through research that the crucible for evaporating the organic or metal materials has an extremely high temperature (e.g., 200° C. to 1500° C.) during the evaporation deposition process. The mask will be heated from the initial room temperature (e.g., 26° C.) to a certain temperature (e.g., 40° C.) when the evaporation deposition material gas is deposited onto the metal mask. In this process, the mask 1 and the display substrate will undergo a certain thermal expansion deformation, thereby intensifying the deformation of mask 1. For example, the mask 1 will undergo deformations such as sagging under the effect of the thermal expansion deformation, as shown in FIG. 1, where 1 indicates the original mask and 1′ indicates the mask that has undergone sagging deformation.

In view of this, an embodiment of the present disclosure provides a mask that can offset the deformation more accurately by compensating the shape and size of the mask opening region. This allows the shape and size of the mask openings of the mask opening region to approach the target state more closely during the mask tensioning and evaporation deposition, which can effectively ameliorate the color mixing defect and increase the product yield.

In an embodiment of the present disclosure, the mask 1 is disposed above the display substrate 40 (referring to FIG. 18). The display substrate 40 includes an active area. The active area includes a plurality of pixel openings. The mask 1 is adapted to allow the evaporation deposition material to be deposited in the pixel openings of the active area.

Referring to FIG. 3, the mask 1 includes a first clamping region 20 and a second clamping region 30 that are opposite to each other in a first direction X, and at least one mask opening region 10 located between the first clamping region 20 and the second clamping region 30. Each mask opening region 10 includes a plurality of mask openings. The mask opening region 10 is in a first initial shape before being tensioned (referring to FIG. 7, which shows the compensated pattern). During the evaporation deposition process, the mask opening region 10 is in a first target shape (referring to FIG. 4). The first initial shape is different from the first target shape.

The first initial shape includes a compensation pattern with respect to the first target shape, and the compensation pattern includes a tensile deformation pattern and a thermal deformation pattern.

It should be noted that the mask opening region 10 is in the first target shape, and the “target shape” refers to the mask opening region 10 of the mask 1 in the target state being located at a preset position, at which the mask openings can be in precise alignment one-to-one with the pixel openings of the display substrate 40. Furthermore, if the sub-pixels to be deposited are arranged in a matrix, the mask opening region 10 in the target state is located at the preset position, and thus the mask openings in the target state are arranged in a matrix that matches the size and position of the sub-pixels to be deposited.

Optionally, the first target shape can be a polygon, a circle, or an ellipse. It can be understood that the first target shape can be other shapes, which is not limited herein. However, in order to ensure the precise positioning between the mask openings and the pixel openings, in an embodiment, the first target shape can be a regular shape, specifically can be an axially symmetrical shape about the centerline extending along the first direction X, or can be an axially symmetrical shape about the centerline extending along the second direction Y. For example, in the embodiment shown in FIG. 4, the first target shape is a rectangle.

In the design process of the mask 1, the mask 1 can be tensioned by actual operation or simulation, and the deformation state information of the mask opening region 10 can be obtained through actual measurement or simulation. Taking the simulation as an example, through simulating a tensioning process of a test mask, it was found that the mask opening region of the test mask deformed in the tensioning direction (e.g., the first direction X) and also deformed in the non-tensioning direction (e.g., the second direction Y). The mask openings in the mask opening region also shifted in position in the first direction X and in the second direction Y. Based on this, the shape and size of the mask opening region of the test mask can be compensated in the first direction X and the second direction Y, so as to make the mask openings within each mask opening region are precisely aligned, without any deviation or with only a slight deviation, one-to-one with the pixel openings of the display substrate when the mask is tensioned.

Furthermore, the evaporation deposition using the test mask can be performed by actual operation or simulation. Taking the simulation of the evaporation deposition process as an example, modeling software can be used to model the evaporation deposition chamber, the mask, the display substrate, the evaporation deposition material, the evaporation deposition conditions, etc., simulating the actual evaporation deposition process to obtain a thermal deformation cloud map of the test mask. Through study of the thermal deformation cloud map of the test mask, it is found that the test mask deforms in the first direction X and the second direction Y. In order to make the compensation more accurate, tensile deformation compensation and thermal deformation compensation can be performed separately on the mask opening region in the first direction X and the second direction Y respectively. In other words, tensile deformation compensation and thermal deformation compensation can be performed on the mask opening region in both the first direction X and the second direction Y, resulting in a first initial shape including a compensation pattern with respect to the first target shape. The compensation pattern includes a tensile deformation pattern and a thermal deformation pattern.

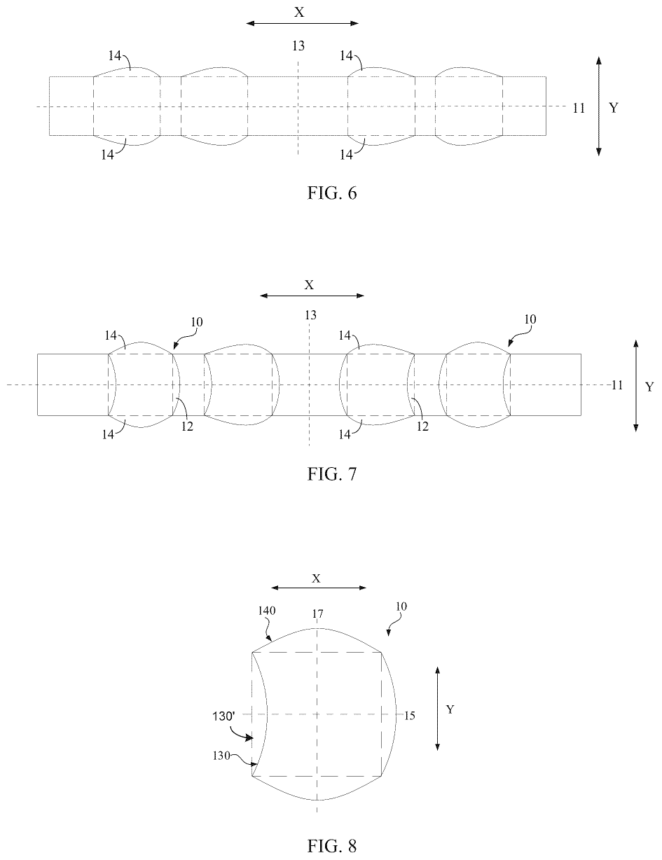

Specifically, referring to FIGS. 5 and 6, a first compensation pattern 12 of the mask opening region 10 in the first direction X can be determined according to tensile deformation trend, tensile position deviation amount, evaporation deposition thermal deformation trend, and evaporation deposition thermal deformation amount of each mask opening region 10 in the first direction X caused by the mask tensioning and the evaporation deposition process. A second compensation pattern 14 of the mask opening region 10 in the second direction Y can be determined according to tensile deformation trend, tensile position deviation amount, evaporation deposition thermal deformation trend, and evaporation deposition thermal deformation amount of each mask opening region 10 in the second direction Y caused by the mask tensioning and the evaporation deposition process. Referring to FIGS. 7 and 8, the mask opening region 10 includes two first edges 130 opposite to each other in the first direction X, and two second edges 140 opposite to each other in the second direction Y, and the two second edges 140 are connected to the two first edges 130. The first compensation pattern 12 is disposed extending along the first edge 130, and the second compensation pattern 14 is disposed extending along the second edge 140.

In this way, pre-compensation is applied for thermal and force collaboratively induced uneven deformation of the mask 1 caused by the mask tensioning and evaporation deposition process. This can reduce the deviation between the positions of the mask openings in the mask 1 and the corresponding pixel openings in the display substrate 40, and diminish the difference between actual and designed boundaries of the evaporation-deposited layer, so as to increase the product yield.

It should be noted that the first direction X and the second direction Y may intersect. In an embodiment, the first direction X and the second direction Y are perpendicular to each other. The first direction X is the longitudinal direction of the mask 1, and is also the tensioning direction of the mask 1. The second direction Y is the width direction of mask 1. Specifically, in the embodiment shown in FIGS. 5 to 8, the first direction X is the horizontal direction of the figures, and the second direction Y is the vertical direction of the figures.

In some embodiments of the present disclosure, as shown in FIGS. 4 and 5, each mask 1 includes a first centerline 11 extending along the first direction X and passing through the center of the mask 1, and a second centerline 13 extending along the second direction Y and passing through the center of the mask 1. As shown in FIG. 8, each mask opening region 10 includes a third centerline 15 extending along the first direction X and passing through the center of the mask opening region 10, and a fourth centerline 17 extending along the second direction Y and passing through the center of the mask opening region 10. In some embodiments, the first centerline 11 of the mask 1 and the third centerline 15 of each mask opening region 10 may be collinear. In some other embodiments, the first centerline 11 of the mask 1 and the third centerline 15 of each mask opening region 10 may be non-collinear, which is not limited herein.

The first compensation pattern 12 is configured to protrude toward the second centerline 13, and the second compensation pattern 14 is configured to protrude away from the first centerline 11. Through actual operation or simulation, the mask tensioning and the evaporation deposition process using the mask 1 can be simulated. Through study of the thermal and force collaboratively induced deformation of the mask 1 caused by the mask tensioning and evaporation deposition, it can be found that the two sides of the mask opening region 10 along the first direction X overall deforms in a protruding manner away from the second centerline 13, and the two sides of the mask opening region 10 along the second direction Y deforms in a protruding manner towards the first centerline 11. By using the above compensation method, the first compensation pattern 12 and the second compensation pattern 14 are formed opposite to the deformation trends of the mask opening region 10 in the first direction X and the second direction Y.

In some embodiments, the mask 1 includes at least two mask opening regions 10 arranged in sequence along the first direction X, and the at least two mask opening regions 10 are symmetrically distributed with respect to the second centerline 13. As shown in FIG. 7, the first compensation pattern 12 of each mask opening region 10 adjacent to the second centerline 13 is configured to protrude outwardly toward the second centerline 13; the first compensation pattern 12 of each mask opening region 10 away from the second centerline 13 is configured to protrude inwardly toward the second centerline 13; and the second compensation pattern 14 is configured to protrude outwardly away from the first centerline 11. In this way, the deviation between the position of the mask openings in each mask opening region 10 and the position of the corresponding pixel openings in the display substrate 40 is reduced, improving the difference between the actual and designed boundaries of the deposited layer, and increasing the product yield.

It should be noted that in order to facilitate the identification of the mask opening region 10 and the compensation to the deformation of the first edge 130 and the second edge 140 of the mask opening region 10, the mask opening region 10 before compensation is shown in a dashed-line box in FIGS. 5 to 8. For example, as shown in FIG. 5, the mask opening region 10 before compensation is rectangular (the dashed-line box), and that is, the first edge 130 and the second edge 140 before compensation are shown in dashed lines, and are perpendicular and connected to each other to form the mask opening region 10 being of a rectangular shape. With compensation along the first direction X, the mask opening region 10 is shown in solid lines in FIGS. 5 to 8, protruding toward the second centerline 13. As such, the first edge shown in the solid lines 130 and the first edge shown in the dashed lines 130′ in FIGS. 5 to 8 define the first compensation pattern 12.

It should also be noted that in the present disclosure, the compensation pattern is configured extending along the first edge 130 and the second edge 140, which means that the compensation pattern itself includes the first edge 130/the second edge 140. For example, as shown in FIGS. 7 and 8, the first compensation pattern 12 not only includes the region defined between the first edge 130′ before compensation (the dashed lines) and the first edge 130 after compensation (the solid lines), but also includes the first edge 130′ before compensation (the dashed lines) and the first edge 130 after compensation (the solid lines) themselves.

Further, the first compensation pattern 12 and the second compensation pattern 14 are both arc shaped, formed by connecting a straight line and an arc line. Through actual operation or simulation of the mask tensioning and evaporation deposition using the mask 1, it can be found that the deformation amounts along the first direction X at different positions on either side of the third centerline 15 of each mask opening region 10 are different from each other, and the deformation amounts along the second direction Y at different positions on either side of the fourth centerline 17 of each mask opening region 10 are different from each other. The arc-shaped compensation patterns described above can precisely pre-compensate at different positions of the mask 1 for the thermal and force collaboratively induced uneven deformation of the mask 1 during the mask tensioning and evaporation deposition process. This can reduce the deviation between the positions of the mask openings in each mask opening region 10 and the corresponding pixel openings in the display substrate 40, and diminish the difference between actual and designed boundaries of the evaporation-deposited layer, thereby increasing the product yield.

In some embodiments, the first compensation pattern 12 is configured to be in an axially symmetrical shape that is symmetrical about the third centerline 15 of the mask opening region 10. For example, as shown in FIG. 8, the first edge 130 of the mask opening region 10 is arc shaped in an initial state (after compensation), and the third centerline 15 evenly divides the compensated first edge 130 (the solid line). In this way, the deformation compensation of the mask opening region 10 can be more uniform, thereby reducing the uneven deformation of the mask 1 caused by the mask tensioning, and improving the compensation effect of the mask 1. Further, the two second compensation patterns 14 of the same mask opening region 10 are symmetrically arranged with respect to the third centerline 15 of the mask opening region 10. For example, as shown in FIG. 8, the two second edges 140 of the mask opening region 10 are arc shaped in an initial state (after compensation) and are symmetrically about the third centerline 15 of the mask opening region 10. In this way, the deformation compensation of the mask opening region 10 can be more uniform, thereby reducing the uneven deformation of the mask 1 caused by the mask tensioning, and improving the compensation effect of the mask 1.

The inventors of the present application further found through research that in these embodiments, it may be still not possible to completely avoid the misalignment of the mask openings. For example, the position offsets of the mask openings at different positions are different. For example, the position offset of the mask openings adjacent to the first edge 130 and second edge 140 of the mask opening region 10 is different from the position offset of the mask openings adjacent to the centerline of the mask opening area 10. In some embodiments, the position offset compensation can be performed on the basis of each mask opening. However, if precise position offset compensation is performed for each mask opening based on a fitted deformation curve, it would involve a large computational load. Not wishing to be limited by theory, in some embodiments, the mask openings can be divided into regions. The adjacent mask openings with similar types of deformations are divided into the same region, and the position offsets of the mask openings within the same region are compensated using the same method, reducing the workload of compensation and improving efficiency. However, with the advancement of display technology and the pursuit of high-resolution and high-PPI display, the regional compensation method still has significant workload and difficulty. Moreover, as the mask openings are in different sizes, the complexity of the regional compensation method is increased.

In some embodiments, the arrangement of the mask openings can be improved on the basis of the deformation trend and the deformation amount of the mask opening region. Referring to FIG. 9, in some embodiments, the mask opening region 10 includes a plurality of mask openings 16 arranged at intervals. The plurality of mask openings 16 are arranged in rows along the first direction X and in columns along the second direction Y. All the mask openings 16 in the same mask opening region 10 have the same size c along the first direction X, and any two adjacent mask openings 16 in the same row are equally spaced along the first direction X. In the multiple rows of mask openings 16 located on the same side of the third centerline 15 along the second direction Y, the closer the mask openings 16 in the same row to the third centerline 15, the greater the spacing in the first direction X between the two adjacent mask openings 16 in the same row. Specifically, as shown in FIG. 9, the mask openings 16 in the lower row are closer to the third centerline 15 of the mask opening region 10, so that the spacing f1 between the two adjacent mask openings 16 in the upper row is less than the spacing f2 between the two adjacent mask openings 16 in the lower row. The study found that during the mask tensioning along the first direction X and the evaporation deposition process using the mask 1, the mask openings 16 closer to the third centerline 15 of the mask opening area 10 are subjected to greater tension and thermal stress. Correspondingly, the deformation degree of the mask openings 16 is also increased, leading to a decrease in the position precision of the mask openings 16. Therefore, increasing the spacing between the two adjacent mask openings 16 located closer to the third centerline 15 in multiple rows of mask openings 16 on the same side of the third centerline 15 can change the physical properties of the corresponding region of the row in which the mask openings 16 are located. This can offset the different deformation degrees of the mask openings 16 along the second direction Y within the mask opening region 10, thereby improving the position precision of the mask openings 16.

It can be understood that by having all the mask openings 16 in the same mask opening region 10 with the same size c along the first direction X and by equally spacing any two adjacent mask openings 16 in the same row, regional and regular variations in physical properties can be present in the mask opening region 10 along the second direction Y. This is beneficial for accurately controlling the position precision of the mask openings 16 through compensation patterns, enhancing the compensation effect.

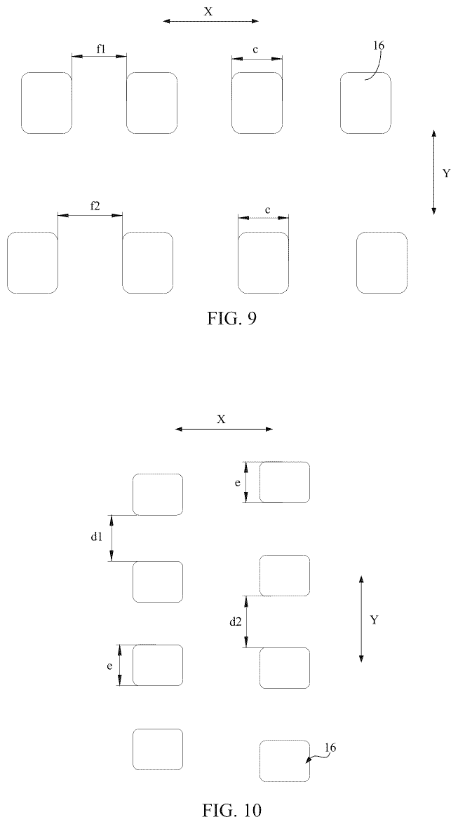

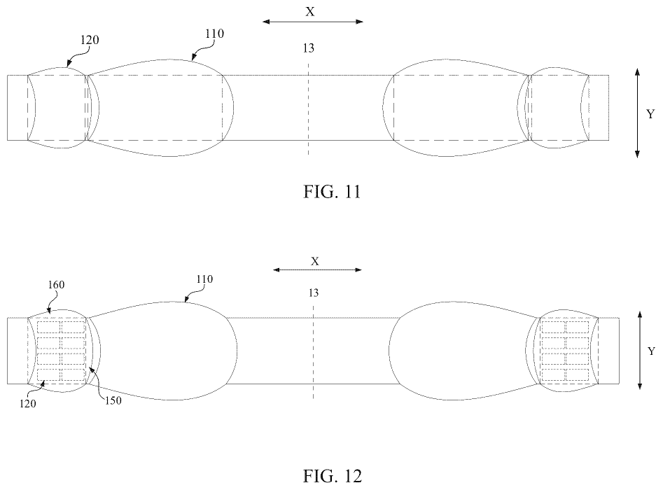

In some embodiments, referring to FIG. 10, the mask opening region 10 includes a plurality of mask openings 16 arranged at intervals. The plurality of mask openings 16 are arranged in rows along the first direction X and in columns along the second direction Y. All the mask openings 16 in the same mask opening region 10 have the same size e along the second direction Y, and any two adjacent mask openings 16 in the same column are equally spaced. In the multiple columns of mask openings 16 located on the same side of the fourth centerline 17 along the first direction X, the closer the mask openings 16 in the same column to the fourth centerline 17, the greater the spacing in the second direction Y between the two adjacent mask openings 16 in the same column. For example, as shown in FIG. 10, the mask openings 16 in the right column are closer to the fourth centerline 17 of the mask opening region 10, so that the spacing d1 between the two adjacent mask openings 16 in the left column is less than the spacing d2 between the two adjacent mask openings 16 in the right column. The study found that during the mask tensioning along the first direction X, due to the tension along the first direction X, the mask opening region 10 can contract along the second direction Y. The closer the mask openings 16 are to the fourth centerline 17, the greater the contraction degree of the mask openings 16 along the second direction Y, leading to a decrease in the position precision of the mask openings 16. Additionally, due to the effect of heat, the thermal deformation degrees of the mask opening regions 10 in the second direction Y are different from each other at different positions along the first direction X. Therefore, by considering both tensile deformation and thermal deformation, increasing the spacing between the two adjacent mask openings 16 located closer to the fourth centerline 17 in multiple columns of mask openings 16 on the same side of the fourth centerline 17 can change the physical properties of the corresponding region of the column in which the mask openings 16 are located. This can offset the different deformation degree of the mask openings 16 along the first direction X within the mask opening region 10, thereby improving the position precision of the mask openings 16.

In order to ensure display uniformity, the sub-pixel arrangement in the pixel arrangement structure should be as uniform as possible, for example, arranged in rows and columns. Correspondingly, the mask openings 16 are also arranged in rows along the first direction X and in columns along the second direction Y. However, the arrangement in rows or columns here does not mean that the connected center lines of the mask openings 16 in the same row or column must be the same straight line parallel to the first direction X or the second direction Y. Instead, the mask openings 16 are substantially arranged in rows along the first direction X and substantially arranged in columns along the second direction Y. For example, the connected center lines of the mask openings 16 in the same row or column can form a polyline.

As described above, with the development of display technology, there is a growing demand for high-quality display screens, and the efficiency and cost of the display screen production are crucial. In view of this, in order to improve production efficiency, the same mask 1 can be used for manufacturing different types of display panels, thus greatly improving efficiency and reducing the cost in producing the display screens. In some embodiments, the mask 1 includes a first-type mask opening region 110 and a second-type mask opening region 120, and the area of the first-type mask opening region 110 is greater than the area of the second-type mask opening region 120.

Referring to FIG. 11, in an embodiment, the plurality of mask opening regions 10 located on the same side of the second centerline 13 include a first-type mask opening region 110 and a second-type mask opening region 120, which are different in area and adjacently arranged in the first direction X away from the center of the mask 1. The area of the first-type mask opening region 110 is greater than the area of the second-type mask opening region 120. It can be understood that due to the different areas of the first-type mask opening region 110 and the second-type mask opening region 120, the physical properties such as stress of the first-type mask opening region 110 and the second-type mask opening region 120 are different, so that the first-type mask opening region 110 and the second-type mask opening region 120 have different tensile rates along the first direction X. The compensation amount of the first compensation pattern 12 of the first-type mask opening region 110 can be configured to be different from the compensation amount of the first compensation pattern 12 of the second-type mask opening region 120, so that the different deformation amounts caused by the different tensile rates of the mask opening regions 10 along the first direction X can offset, achieving better compensation effects for different types of mask opening regions 10 in the first direction X. Correspondingly, the compensation amount of the second compensation pattern 14 of the first-type mask opening region 110 can be configured to be different from the compensation amount of the second compensation pattern 14 of the second-type mask opening region 120, achieving better compensation effects for different types of mask opening regions 10 in the second direction Y.

For another example, in another embodiment, at least two second-type mask opening regions 120 are provided, and the at least two second-type mask opening regions 120 are arranged adjacently to form a mask compensating region (not labeled). In the embodiment shown in FIG. 12, the number of the second-type mask opening regions 120 is eight, and the eight second-type mask opening regions 120 are arranged in a matrix to form the mask compensating region. The shape of the mask compensating region before being tensioned includes a third compensation pattern 150 extending along the edge of the mask compensating region in the first direction X and a fourth compensation pattern 160 extending along the edge of the mask compensating region in the second direction Y, with respect to the shape of the mask compensating region during the evaporation deposition process. In this way, the mask compensating region is compensated as a whole, achieving effective compensation in both the first direction X and the second direction Y while satisfying the arrangement of various types of mask opening regions. This can reduce the deviation between the positions of the mask openings in each mask opening region and the corresponding pixel openings in the display substrate, and diminish the difference between actual and designed boundaries of the evaporation-deposited layer, thereby increasing the product yield. It is worth mentioning that the third compensation pattern 150 and the fourth compensation pattern 160 compensate for both the tensile deformation and the thermal deformation of the mask compensating region respectively in the first direction X and the second direction Y. In other words, the third compensation pattern 150 and the fourth compensation pattern 160 both include a tensile deformation pattern and a thermal deformation pattern.

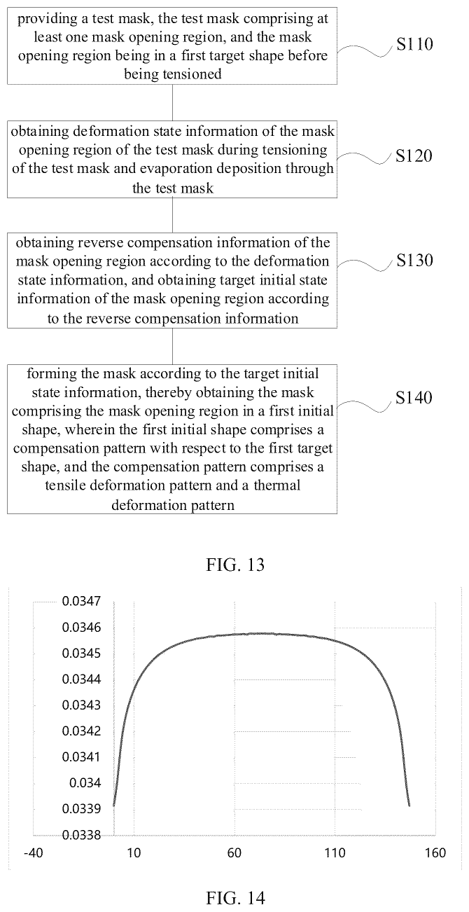

Referring to FIG. 13, an embodiment of the present disclosure further provides a method for manufacturing a mask. The method includes S110 to S140.

S110: provide a test mask, wherein the test mask includes at least one mask opening region 10, and the mask opening region 10 is in a first target shape before being tensioned.

The test mask can further include a first clamping region 20 and a second clamping region 30 opposite to each other in the first direction X. At least one mask opening region 10 is disposed between the first clamping region 20 and the second clamping region 30. During the tensioning of the test mask, the first clamping region 20 and the second clamping region 30 of the test mask can be clamped by mechanical arms for applying tension. In some embodiments, the test mask can also include other regions, such as dummy mask opening regions, welding regions, cutting regions, etc., which are not limited herein.

It should be noted that the test mask refers to the mask whose mask openings within the mask opening region before being tensioned are in the preset position and can be accurately aligned with the pixel openings of the display substrate 40. Thus, the shape of the mask opening region of the test mask is exactly the same as the first target shape described above.

The mask opening region 10 is in the first target shape, and the “target shape” refers to the mask opening region 10 of the mask 1 in the target state being located at a preset position, at which the mask openings can be in precise alignment one-to-one with the pixel openings of the display substrate 40. Furthermore, if the sub-pixels to be deposited are to be arranged in a matrix, the mask opening region 10 in the target state is located at the preset position, and thus the mask openings in the target state are arranged in a matrix that matches the size and position of the sub-pixels to be deposited.

S120: obtain deformation state information of the mask opening region of the test mask during mask tensioning and evaporation deposition of the test mask.

The test mask can be tensioned by clamping the first clamping region 20 and the second clamping region 30 with mechanical arms, which applies a tensioning force along the length direction of the test mask. At this time, the test mask deforms due to the force, and the mask opening region 10 also deforms accordingly.

Simulation can be performed using computer software. For example, the simulation process involves providing a virtual test mask (as shown in FIG. 4) and simulating a tensioning operation on this virtual test mask to obtain deformation state information of the test mask. This method is simple and fast, and enables the acquisition of the required data in a short time period. The actual measurement operation involves providing a real test mask and then performing a tensioning operation on the test mask to obtain deformation state information through an actual measurement.

The deformation state information includes a tensile deformation trend, a tensile position deviation amount, an evaporation deposition thermal deformation trend, and an evaporation deposition thermal deformation amount of multiple position points within the mask opening region 10 in the first direction and the second direction. Specifically, the deformation trends (i.e., the tensile deformation trend and the thermal deformation trend) and the position offsets (i.e., the tensile position deviation amount and the evaporation deposition thermal deformation amount), in the first direction X and the second direction Y, of specified position points in the mask opening region 10 can be obtained through simulation or actual operation.

S130: obtain reverse compensation information of the mask opening region according to the deformation state information, and obtain target initial state information of the mask opening region according to the reverse compensation information.

The reverse compensation information can include deformation compensation values at multiple position points of the mask opening region 10 or deformation compensation curves of the mask opening region 10 in the first direction and the second direction. For example, when the deformation amount at a certain position point of the mask opening region 10 of the test mask is M, the deformation compensation value at this position point of the mask opening region is −M. In this way, the deformation compensation values at each position point of the mask opening region can be obtained. The deformation compensation curve of the mask opening region can be obtained by fitting a curve to the deformation compensation values.

In some embodiments, the method further includes S131 to S132.

S131: obtain a deformation curve of the mask opening region in the first direction and the second direction according to the deformation state information of the mask opening region in the first direction and the second direction;

S132: obtain the deformation compensation curve of the mask opening region in the first direction and the second direction according to the deformation curve of the mask opening region in the first direction and the second direction.

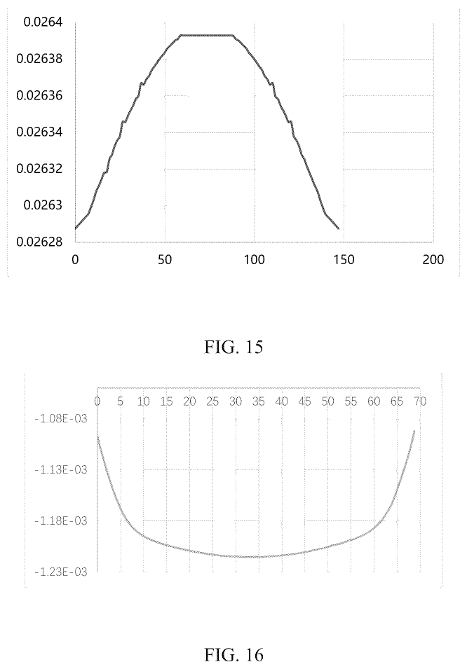

Specifically, the deformation compensation curve of the mask opening region can be obtained through a symmetry processing on the deformation curve. For example, the first fitted deformation curve of the mask opening region 10 in the first direction X and the second fitted deformation curve of the mask opening region 10 in the second direction Y can be subjected to a symmetry processing to form the corresponding deformation compensation curves in the respective directions. FIGS. 14 and 15 respectively show the fitted deformation curves on both sides of the mask opening region 10 along the first direction X, where the horizontal axis represents the original coordinates of the specified position points in the mask opening region 10 along the second direction Y, and the vertical axis represents the position offsets of the specified position points in the deformed mask opening region 10. FIG. 16 shows the fitted deformation curve on both sides of the mask opening region 10 along the second direction Y, where the horizontal axis represents the original coordinates of the specified position points in the mask opening region 10 along the first direction X, and the vertical axis represents the position offsets of the specified position points in the deformed mask opening region 10.

It should be understood that the deformation curve of the mask opening region 10 formed by selecting multiple specified position points is not a smooth curve. Compensating for position offsets based on such a curve can be time-consuming. Therefore, in some embodiments of the present disclosure, the deformation curves can be fitted by using such as linear fitting, polynomial fitting or other nonlinear fittings to obtain fitted deformation curves, according to which position offset compensation can be applied to the mask openings, so as to reduce the workload for compensation and improve the compensation efficiency. In some embodiments, the target initial state information can include a target initial shape and a target initial size of the mask opening region 10. For example, the deformation compensation curve can be superimposed on the initial state (shape and size) of the mask opening region 10 of the test mask, thereby obtaining the target initial state information of the mask opening region 10.

S140: form the mask according to the target initial state information, thereby obtaining the mask including the mask opening region in a first initial shape.

The first initial shape includes a compensation pattern with respect to the first target shape, and the compensation pattern includes a tensile deformation pattern and a thermal deformation pattern. Specifically, the mask opening region of the formed mask includes two first edges 130 opposite to each other in the first direction X, and two second edges 140 opposite to each other in the second direction Y. The compensation pattern includes a first compensation pattern 12 extending along the first edge 130 and a second compensation pattern 14 extending along the second edge 140.

For a better understanding of the inventive concept of the present disclosure, the method for manufacturing the mask in the present disclosure will be described below with different specific embodiments. The difference between the following different embodiments mainly lies in the size of the mask opening region 10 along the first direction X and the arrangement of the mask opening region 10 in the mask 1. The deformation calculation method of the position points in the corresponding mask opening region 10 will also be varied correspondingly, which still follows the inventive concept of the present disclosure.

In some embodiments, the test mask includes a first centerline 11 extending along the first direction X and passing through the center of the test mask, and a second centerline 13 extending along the second direction Y and passing through the center of the test mask. The test mask includes a plurality of mask opening regions 10 arranged in sequence along the first direction X, and the plurality of mask opening regions 10 are symmetrically distributed with respect to the second centerline 13. The plurality of mask opening regions 10 located on the same side of the second centerline 13 include a first-type mask opening region 110 and a second-type mask opening region 120, which are different in area and adjacently arranged in the direction away from the center of the test mask. The mask opening region 10 of the test mask includes two first edges 130 opposite to each other in the first direction X, and two second edges 140 opposite to each other in the second direction Y.

It can be understood that the tensile rate (c) of the mask opening region 10 satisfies ε=1−F/(E*S), where F is the tensioning force applied to the test mask, E is the elastic modulus of the material of the test mask, and S is the area of the mask opening region 10. It should be noted that all the parameters mentioned above are measured in the International System of Units (SI). For example, the tensioning force F is measured in the unit of Newton (N), and the elastic modulus E is measured in the unit of megapascal (MPa) or Newton per square meter (N/m²). Thus, the unit for the area S is matched to the unit of the elastic modulus E. For example, when the elastic modulus E is measured in the unit of N/m², the unit for the area S is square meters (m²).

However, the inventors of the present application further found through research that the first-type mask opening region 110 and the second-type mask opening region 120 have different distances from the center of the test mask, resulting in that an actual tensile rate δ is not a fixed value relative to the center of the test mask during the tensioning of the test mask along the first direction X but varies with the coordinate in the first direction X in the coordinate system with the center of the test mask as the origin. Therefore, to accurately obtain compensation information for the mask opening regions 10 of different types and distances from the center of the test mask, the inventors of the present application, after thorough research, discovered that for any position point in the second-type mask opening region 120, the coordinates of this position point in the first direction X before and after compensation are denoted as X_{A} and X_{A′}, respectively, and X_{A} and X_{A′} satisfy the following relationship: 6=X_{A′}/X_{A}.

The tensile position deviation amount in the first direction X of any position point A in the second-type mask opening region 120, except that in the first edge 130, caused by the mask tensioning is obtained as follows:

Δf=X_{A′}-X_{A}=X_{A}*δ−X_{A};

δ=X_{A′}/X_{A}=[X_{B′}+(X_{A}−X_{B})*ε₂]/X_{A}=(1/X_{A})*(X_{B′}−X_{B}*ε2)+ε2;

X_{B′}=X_{B}*ε₁

Here, in the two-dimensional coordinate system established with the center of the test mask as the origin: X_{A} represents the coordinate in the first direction X of any position point A in the second-type mask opening region 120, except a position point in the first edge 130, before the test mask is tensioned. X_{A′} represents the coordinate in the first direction X of the same position point A in the second-type mask opening region 120, except the position point in the first edge 130, when the test mask is tensioned. X_{B} represents the coordinate in the first direction X of any position point B in the first edge 130 of the second-type mask opening region 120, adjacent to the center of the test mask, before the test mask is tensioned. X_{B′} represents the coordinate in the first direction X of the same position point B in the first edge 130 of the second-type mask opening region 120, adjacent to the center of the test mask, when the test mask is tensioned. ε₁ represents the tensile rate of the first-type mask opening region 110 adjacent to the second-type mask opening region 120. ε₂ represents the tensile rate of the second-type mask opening region 120.

In this way, the tensile position deviation amount along the first direction X for any position point in the second-type mask opening region 120 adjacent to the first-type mask opening region 110 can be accurately calculated. Consequently, the first fitted deformation curve of the second-type mask opening region 120 can be precisely obtained, allowing for the accurate determination of the compensation amount along the first direction X for the first compensation pattern 12 of the second-type mask opening region 120.

In some embodiments, the mask opening region 10 of the test mask includes a third centerline 15 extending along the first direction X and passing through the center of the mask opening region 10, and a fourth centerline 17 extending along the second direction Y and passing through the center of the mask opening region 10. The test mask includes a plurality of mask opening regions 10 arranged in sequence along the first direction X, and the plurality of mask opening regions 10 are symmetrically distributed with respect to the second centerline 13. At least some mask opening regions 10 located on the same side of the second centerline 13 repetitively arranged along the first direction X toward the direction away from the center of the test mask. In some embodiments, all of the mask opening regions 10 located on the same side of the second centerline 13 are the second-type mask opening regions 120 and are repetitively arranged. In some other embodiments, as shown in FIG. 11, at least one first-type mask opening region 110 can be first arranged, followed by at least one second-type mask opening region 120, which is not limited herein.

In the repetitively arranged mask opening regions 10 in an number of K, the tensile position deviation amount along the first direction X for any position point in the N+1^{th} mask opening region 10 caused by the mask tensioning is obtained as follows:

ΔI_{N+1}=ΔI₁*β;

β=L_{N+1}/L₁, where N is an integer, and N+1≤K

Here, ΔI₁ is for the position point in the mask opening region 10 that is most adjacent to the center of the test mask in the repetitively arranged K mask opening regions 10, and represents the tensile position deviation amount along the first direction X of the position point corresponding to the N+1^{th} mask opening region 10 caused by the mask tensioning. L_{N+1} represents the distance from the fourth centerline 17 of the N+1^{th} mask opening region 10 to the center of the test mask. L₁ represents the distance from the fourth centerline 17 of the first mask opening region 10 that is most adjacent to the center of the test mask in the repetitively arranged K mask opening regions 10 to the center of the test mask.

For example, as shown in FIG. 11, in some embodiments, in the plurality of mask opening regions 10 located on the same side of the second centerline 13, at least one first-type mask opening region 110 and at least one second-type mask opening region 120 are sequentially arranged along the first direction X away from the center of the test mask. In the mask design, the tensile position deviation amount caused by the mask tensioning of a specified position point in the first-type mask opening region 110 that is most adjacent to the center of the test mask can be first calculated. Then, based on the different distances between the respective fourth centerlines 17 of the repetitively arranged first-type mask opening regions 110 and the center of the test mask, the tensile position deviation amounts caused by the mask tensioning can be proportionally calculated corresponding to the specified position point for the position points in the repetitively arranged different first-type mask opening regions 110. Similarly, the tensile position deviation amount caused by the mask tensioning of a specified position point in the second-type mask opening region 120 that is most adjacent to the center of the test mask can be first calculated. Then, the tensile position deviation amounts caused by the mask tensioning can be proportionally calculated corresponding to the specified position point for the position points in the repetitively arranged different second-type mask opening regions 120.

In this way, for the plurality of mask opening regions 10 arranged repetitively, a proportional compensation can be applied based on their respective distances from the center of the test mask 1, thus simplifying the compensation calculation method, while still obtaining accurate compensation data.

It should be understood that, as shown in FIG. 12, in some embodiments, the plurality of second-type mask opening regions 120 are arranged adjacently to form the mask compensating region. In the mask design, the tensile position deviation amount caused by the mask tensioning of a specified position point in the first-type mask opening region 110 that is most adjacent to the center of the test mask can be first calculated. Then, based on the different distances between the fourth centerlines 17 of the repetitively arranged first-type mask opening regions 110 and the center of the test mask, the tensile position deviation amounts caused by the mask tensioning can be proportionally calculated corresponding to the specified position point for the position points in the repetitively arranged different first-type mask opening regions 110. Similarly, the tensile position deviation amount caused by the mask tensioning of a specified position point in the mask compensating region that is most adjacent to the center of the test mask can be first calculated. Then, the tensile position deviation amounts caused by the mask tensioning can be proportionally calculated corresponding to the specified position point for the position points in the repetitively arranged different mask compensating regions.

In some embodiments, the evaporation deposition thermal deformation amount in the first direction X of any position point in the mask opening region 10 of the test mask is obtained as follows:

A_{Ex}=(B−A)*H_{y}/2

Here, A represents the thermal expansion coefficient of the test mask 1, B represents the thermal expansion coefficient of the display substrate 40, and Ely represents the size of the mask opening region 10 along the second direction Y.

Correspondingly, the evaporation deposition thermal deformation amount in the second direction Y of any position point in the mask opening region 10 is obtained as follows:

Δ_{Ey}=(B−A)*Hₓ/2

Here, A represents the thermal expansion coefficient of the test mask, B represents the thermal expansion coefficient of the display substrate 40, and Hₓ represents the size of the mask opening region 10 along the first direction X.

Based on the same inventive concept, the present disclosure further provides a mask assembly, including a mask frame 2 (referring to FIG. 2) and one or more masks 1 as described in any of the above embodiments.

The plurality of masks 1 are arranged sequentially along the second direction Y perpendicular to the first direction X (i.e., the tensioning direction) and fixed on the mask frame 2.

An embodiment of the present disclosure further provides a method for manufacturing a mask assembly, and adopts the mask assembly obtained by the manufacturing method to form at least one functional layer of a display substrate. The functional layer includes, for example, any functional layer with a certain pattern, such as the light-emitting layer in the light-emitting device of the display substrate. The display substrate produced by this method has relatively high precision without defects such as dark spots and color mixing.

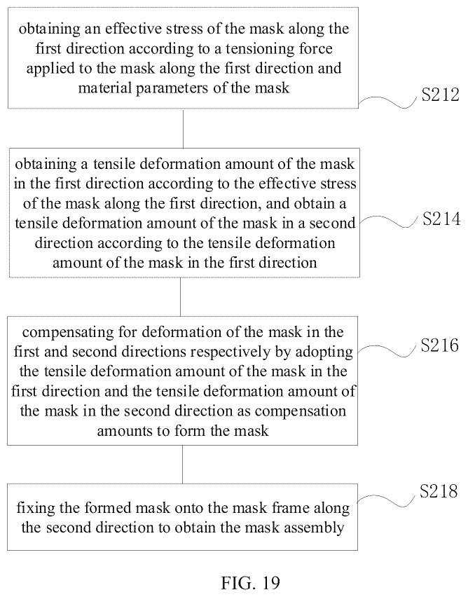

Referring to FIG. 19, in some embodiments, the method for manufacturing the mask assembly includes S212 to S218.

S212: obtain the effective stress of the mask along the first direction according to the tensioning force applied to the mask along the first direction and the material parameters of the mask.

S214: obtain the tensile deformation amount of the mask in the first direction according to the effective stress of the mask along the first direction, and obtain the tensile deformation amount of the mask in the second direction according to the tensile deformation amount of the mask in the first direction; the second direction is perpendicular to the first direction.

Specifically, the deformation amount of the mask in the first direction can be calculated according to Hooke's law.

For example, the deformation amount of the mask in the first direction X can be calculated according to following formula:

Δ_{L1}=F_{effective stress}*L_{original}/E*Aₘₐₛₖ
where Δ_{L1} represents the deformation amount of the mask in the first direction X, F_{effective force} represents the effective stress of the mask along the first direction, L_{original} represents the original length of the mask, E represents the elastic modulus of the mask (a constant related to the material of the mask), and Aₘₐₛₖ represents the area of the mask.

The deformation amount of the mask in the second direction can be calculated according to the Poisson's ratio formula.

For example, the deformation amount of the mask in the second direction Y can be calculated according to following formula:

Δ_{L2}=Δ_{L1}*U
where Δ_{L1} is the deformation amount of the mask in the first direction X, Δ_{L2} is the deformation amount of the mask in the second direction Y, and U is the Poisson's ratio of the material of the mask.

S216: compensate for the deformation of the mask in the first and second directions by respectively using the tensile deformation amount of the mask in the first direction and the tensile deformation amount of the mask in the second direction as compensation amounts to form the mask.

It can be understood that during the process of the mask tensioning, the mask cannot maintain its shape and size as before being tensioned. The length of the mask along the tensioning direction will be increased, and the width will be decreased. Therefore, both the shape and size of the mask will be changed before and after being tensioned. Consequently, there is a need to overall compensate the mask 1.

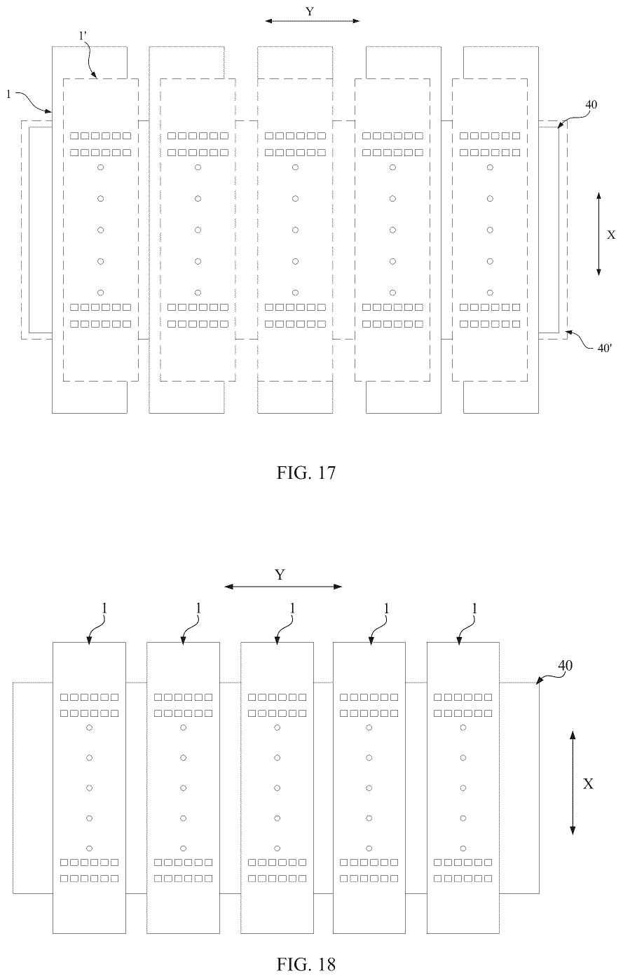

Specifically, the deformation amount of the mask in the first direction X can be used as the compensation amount of the mask in the first direction, and the deformation amount of the mask in the second direction Y can be used as the compensation amount of the mask in the second direction Y, thus performing reverse compensation to offset the deformation generated during the process of the mask tensioning. This results in the size of the tensioned mask being similar to that of the test mask, enhancing the dimensional precision in mask manufacturing. For example, referring to FIG. 17, the solid frame 1 and the dashed frame 1′ respectively represents the masks before and after compensation. The compensated mask 1′ has a reduced size in the length direction (the first direction X) compared to the uncompensated mask 1. It can be understood that during the tensioning process, the mask contracts in its width direction (the second direction Y). Therefore, the compensated mask 1′ has an increased size in the width direction (the second direction Y) compared to the uncompensated mask 1.

S218: fix the formed mask on the mask frame along the second direction to obtain the mask assembly.

Specifically, the mask can be welded to the mask frame.

It can be understood that the mask expands when being heated during the evaporation deposition process. As the thermal expansion coefficient of the mask material is smaller than that of the display substrate, the expansion deformation of the mask is smaller than that of the display substrate. Referring to FIG. 17, the solid frame 40 and the dashed frame 40′ respectively represents the deformation of the display substrate before and during the evaporation deposition process. During the evaporation deposition process, the display substrate expands outwardly when being heated, resulting in defects such as misalignment with the mask openings.

Therefore, displacement compensation can be applied to the mask in the second direction Y. In some embodiments, S218 includes S2182 and S2186.

S2182: obtain position deviation data of the mask in the second direction Y during the evaporation deposition process.

The position deviation data of the mask in the second direction Y can be obtained by simulating the evaporation deposition process using computer software through simulation.

S2184: perform displacement compensation to the mask according to the position deviation data, thereby obtaining position data of the compensated mask.

In some embodiments, the plurality of masks 1 are arranged along the second direction Y. The distances between different masks 1 and the center of the mask assembly are different. Therefore, different masks can be subjected to different displacement compensations according to their respective distances from the center of the mask assembly.

In the embodiment shown in FIG. 17, the mask assembly includes M masks 1 sequentially arranged along the second direction Y on the mask frame 2, where M is an odd number, and M≥3. As shown in FIGS. 17 and 18, the first centerline 11 of one mask 1 coincides with the symmetric axis of the mask assembly. M-1 masks 1 are symmetrically arranged on both sides of the symmetric axis of the mask assembly along the second direction Y. Among the symmetrically arranged M-1 masks 1, the farther the mask 1 from the center of the mask assembly, the greater the displacement compensation of the mask 1, ensuring precise compensation of the mask 1.

In an embodiment, the position deviation data of each mask 1 in the second direction Y is obtained as follows:

ΔP=(B−A)*T/2

Here, A represents the thermal expansion coefficient of the mask 1, B represents the thermal expansion coefficient of the display substrate 40, and T represents the distance between the first centerline 11 of the mask 1 and the symmetric axis of the mask assembly along the second direction Y.

In this way, the thermal compensation amounts of each mask 1 in the first direction X and the second direction Y can be accurately calculated.

S2186: fix the mask onto the mask frame along the second direction according to the position data of the compensated mask.

Specifically, the mask can be welded to the mask frame according to the position data of the compensated mask.

In some embodiments, thermal compensation can be applied to the mask in the first direction X. Furthermore, the thermal compensation and the tension compensation can be coupled to obtain the final compensation trend and compensation amount. The evaporation deposition thermal deformation amount in the first direction X of each mask 1 can be obtained as follows:

ΔJ=(B−A)*Q/2;

Here, A represents the thermal expansion coefficient of the mask 1, B represents the thermal expansion coefficient of the display substrate 40, and Q represents the size of the at least one mask opening region 10 along the first direction X.

In the case of using “including”, “having”, and “comprising” as described herein, another component can also be added unless clear definitive terms such as “only”, “consisting . . . of”, etc., are used. Unless stated otherwise, singular terms can encompass their plural forms and should not be understood as limited to the quantity of one.

The technical features of the above embodiments can be combined arbitrarily. In order to make the description concise, not all possible combinations of the technical features are described in the embodiments. However, as long as there is no contradiction in the combination of these technical features, the combinations should be considered as in the scope of the present disclosure.

The above-described embodiments are only several implementations of the present disclosure, and the descriptions are relatively specific and detailed, but they should not be construed as limiting the scope of the present disclosure. It should be understood that various modifications and improvements can be made by those of ordinary skill in the art without departing from the concept of the present disclosure, and all fall within the protection scope of the present disclosure. Therefore, the patent protection scope of the present disclosure shall be defined by the appended claims.

What is claimed is:

1. A mask comprising:
a first clamping region and a second clamping region opposite to each other in a first direction; and
at least one mask opening region disposed between the first clamping region and the second clamping region;
wherein the mask opening region is in a first initial shape before being tensioned, the mask opening region is in a first target shape during an evaporation deposition process, and the first initial shape is different from the first target shape; and
the first initial shape comprises a compensation pattern with respect to the first target shape, and the compensation pattern comprises a tensile deformation pattern and a thermal deformation pattern.

2. The mask according to claim 1, wherein the mask opening region comprises two first edges opposite to each other in the first direction, two second edges opposite to each other in a second direction, and the two second edges are connected to the two first edges; the first direction is a tensioning direction of the mask, and the second direction is perpendicular to the first direction; and
the compensation pattern comprises at least one first compensation pattern extending along the first edge and at least one second compensation pattern extending along the second edge.

3. The mask according to claim 2, comprising a first centerline extending along the first direction and passing through the center of the mask, and a second centerline extending along the second direction and passing through the center of the mask; the mask opening region comprises a third centerline extending along the first direction and passing through the center of the mask opening region, and a fourth centerline extending along the second direction and passing through the center of the mask opening region;
the first compensation pattern is configured to protrude toward the second centerline, and the second compensation pattern is configured to protrude away from the first centerline.

4. The mask according to claim 3, wherein the at least one second compensation pattern comprises two second compensation patterns symmetrically arranged with respect to the third centerline of the mask opening region.

5. The mask according to claim 3, wherein the mask opening region comprises a plurality of mask openings arranged at intervals;
the plurality of mask openings are arranged in rows along the first direction and in columns along the second direction;
all the mask openings in a same mask opening region have a same size along the first direction, and any two adjacent mask openings in a same row are equally spaced along the first direction;
in the rows of mask openings located on a same side of the third centerline along the second direction, the closer the mask openings in the same row to the third centerline, the greater the spacing in the first direction between two adjacent mask openings in the same row.

6. The mask according to claim 3, wherein the mask opening region comprises a plurality of mask openings arranged at intervals;
the plurality of mask openings are arranged in rows along the first direction and in columns along the second direction;
all the mask openings in a same mask opening region have a same size along the second direction, and any two adjacent mask openings in a same column are equally spaced along the second direction;
in the columns of mask openings located on a same side of the fourth centerline along the first direction, the closer the mask openings in the same column to the fourth centerline, the greater the spacing in the second direction between two adjacent mask openings in the same column.

7. The mask according to claim 3, the at least one mask opening region comprises at least two mask opening regions arranged in sequence along the first direction, and the at least two mask opening regions are symmetrically distributed with respect to the second centerline.

8. The mask according to claim 1, wherein the at least one mask opening region comprises a first-type mask opening region and a second-type mask opening region, and the area of the first-type mask opening region is greater than the area of the second-type mask opening region.

9. The mask according to claim 8, wherein the second-type mask opening region comprises at least two second-type mask opening regions, and the at least two second-type mask opening regions are arranged adjacently to form a mask compensating region;
the mask compensating region before being tensioned, with respect to the mask compensating region during the evaporation deposition process, comprises a third compensation pattern extending along an edge of the mask compensating region in the first direction and a fourth compensation pattern extending along another edge of the mask compensating region in a second direction;
the first direction is a tensioning direction of the mask, and the second direction is perpendicular to the first direction.

10. A method for manufacturing a mask, comprising:
providing a test mask, the test mask comprising at least one mask opening region, and the mask opening region being in a first target shape before being tensioned;
obtaining deformation state information of the mask opening region of the test mask during tensioning of the test mask and evaporation deposition through the test mask, the deformation state information comprising a tensile deformation trend, a tensile position deviation amount, an evaporation deposition thermal deformation trend, and an evaporation deposition thermal deformation amount of multiple position points within the mask opening region in a first direction and a second direction, wherein the first direction is parallel to a tensioning direction of the test mask, and the second direction is perpendicular to the first direction;
obtaining reverse compensation information of the mask opening region according to the deformation state information, and obtaining target initial state information of the mask opening region according to the reverse compensation information; and
forming the mask according to the target initial state information, thereby obtaining the mask comprising the mask opening region in a first initial shape, wherein the first initial shape comprises a compensation pattern with respect to the first target shape, and the compensation pattern comprises a tensile deformation pattern and a thermal deformation pattern.

11. The method according to claim 10, wherein the mask opening region of the formed mask comprises two first edges opposite to each other in the first direction, two second edges opposite to each other in the second direction, and the two second edges are connected to the two first edges;
the compensation pattern comprises a first compensation pattern extending along the first edge and a second compensation pattern extending along second edge.

12. The method according to claim 10, wherein the reverse compensation information comprises deformation compensation values at the multiple position points of the mask opening region or deformation compensation curves of the mask opening region in the first direction and the second direction.

13. The method according to claim 10, wherein the test mask comprises a first centerline extending along the first direction and passing through the center of the test mask, and a second centerline extending along the second direction and passing through the center of the test mask;
the at least one mask opening region of the test mask comprises a plurality of mask opening regions arranged in sequence along the first direction, the plurality of mask opening regions are symmetrically distributed with respect to the second centerline, the plurality of mask opening regions located on a same side of the second centerline comprise a first-type mask opening region and a second-type mask opening region, the first-type mask opening region and the second-type mask opening region are different in area and adjacently arranged in a direction away from the center of the test mask;
each of the mask opening regions of the test mask comprises two first edges opposite to each other in the first direction, and two second edges opposite to each other in the second direction; the tensile position deviation amount in the first direction of any position point in the second-type mask opening region excluding the first edge are obtained through:
Δf=X_{A′}−X_{A};
Y_{A′}=Y_{A}*δ;
δ=(1/X_{A})*(X_{B′}−X_{B}*ε2)+ε2;
Y_{B′}=Y_{B}*ε₁;
wherein in a two-dimensional coordinate system established with the center of the test mask as the origin:
X_{A} represents a coordinate in the first direction of any position point in the second-type mask opening region excluding the first edge, before the test mask is tensioned;
X_{A′} represents a coordinate in the first direction of any position point in the second-type mask opening region excluding the first edge, when the test mask is tensioned;
X_{B} represents a coordinate in the first direction of any position point in the first edge of the second-type mask opening region, adjacent to the center of the test mask, before the test mask is tensioned;
X_{B′} represents a coordinate in the first direction of any position point in the first edge of the second-type mask opening region, adjacent to the center of the test mask, when the test mask is tensioned;
ε₁ represents a tensile rate of the first-type mask opening region adjacent to the second-type mask opening region;
ε₂ represents a tensile rate of the second-type mask opening region; and
the tensile rate, represented by ε, of the mask opening region satisfies ε=1−F/(E*S), where F represents a tensioning force applied to the test mask, E represents an elastic modulus of a material of the test mask, and S represents an area of the mask opening region.

14. The method according to claim 10, wherein the test mask comprises a first centerline extending along the first direction and passing through the center of the test mask, and a second centerline extending along the second direction and passing through the center of the test mask;
the mask opening region of the test mask comprises a third centerline extending along the first direction and passing through the center of the mask opening region, and a fourth centerline extending along the second direction and passing through the center of the mask opening region;
the at least one mask opening region of the test mask comprises a plurality of mask opening regions arranged in sequence along the first direction, and the plurality of mask opening regions are symmetrically distributed with respect to the second centerline; at least some of the mask opening regions located on a same side of the second centerline repetitively arranged along the first direction toward the direction away from the center of the test mask;
in the repetitively arranged mask opening regions in an amount of K, the mask opening region being most adjacent to the center of the test mask is the 1^{st} mask opening region, the tensile position deviation amount along the first direction for any position point X in the N+1^{th} mask opening region caused by the tensioning of the test mask is obtained through:
ΔI_{N+1}=ΔI₁*β;
β=L_{N+1}/L₁, where N is an integer, and N+1≤K;
wherein ΔI₁ represents the tensile position deviation amount along the first direction of a position point Y in the 1^{st} mask opening region caused by the tensioning of the test mask, the position point Y corresponds to the any position point X in the N+1^{th} mask opening region;
L^{N+1} represents the shortest distance from the fourth centerline of the N+1^{th} mask opening region to the center of the test mask; and
L₁ represents the shortest distance from the fourth centerline of the 1st first mask opening region to the center of the test mask.

15. The method according to claim 10, wherein the evaporation deposition thermal deformation amount in the first direction of any position point in the mask opening region of the test mask is obtained through:
Δ_{Ex}=(B−A)*H_{y}/2;
wherein A represents a thermal expansion coefficient of the test mask, B represents a thermal expansion coefficient of a display substrate, and H_{y} represents a size of the mask opening region along the second direction; and
the evaporation deposition thermal deformation amount in the second direction of any position point in the mask opening region is obtained through:
A_{Ey}=(B−A)*Hₓ/2;
wherein A represents the thermal expansion coefficient of the test mask, B represents the thermal expansion coefficient of the display substrate, and Hₓ represents a size of the mask opening region along the first direction.

16. The method according to claim 10, wherein the target initial state information comprises a target initial shape information and a target initial size information of the mask opening region.

17. A mask assembly, comprising a mask frame and the mask according to claim 1, arranged on the mask frame.

18. A method for manufacturing the mask assembly according to claim 17, comprising:
obtaining an effective stress of the mask along the first direction according to a tensioning force applied to the mask along the first direction and material parameters of the mask;
obtaining a tensile deformation amount of the mask in the first direction according to the effective stress of the mask along the first direction, and obtaining a tensile deformation amount of the mask in a second direction according to the tensile deformation amount of the mask in the first direction; where the second direction is perpendicular to the first direction;
compensating for deformation of the mask in the first direction and in the second direction respectively by adopting the tensile deformation amount of the mask in the first direction and the tensile deformation amount of the mask in the second direction as compensation amounts to form the mask; and
fixing the formed mask onto the mask frame along the second direction to obtain the mask assembly.

19. The method according to claim 18, wherein the fixing the formed mask on the mask frame along the second direction to obtain the mask assembly comprises:
obtaining position deviation data of the mask in the second direction during the evaporation deposition process;
performing displacement compensation to the mask according to the position deviation data, thereby obtaining position data of a compensated mask; and
fixing the mask onto the mask frame along the second direction according to the position data of the compensated mask.

20. The method according to claim 19, wherein the position deviation data of the mask in the second direction is obtained through:
ΔP=(B−A)*T/2;
wherein A represents a thermal expansion coefficient of the mask, B represents a thermal expansion coefficient of a display substrate, the mask comprises a first centerline extending along the first direction and passing through the center of the mask, and T represents a distance along the second direction between the first centerline of the mask and the center of the mask assembly.
